(19) United States
(12) Patent Application Publication
(10) Pub. No.: US 2026/0136457 A1
(43) Pub. Date: May 14, 2026

(54) PACKAGE STRUCTURE

(71) Applicant: Advanced Semiconductor Engineering, Inc., Kaohsiung (TW)

(72) Inventors: Wei-Hao CHANG, Kaohsiung (TW); Wei-Chun LEE, Kaohsiung (TW)

(73) Assignee: Advanced Semiconductor Engineering, Inc., Kaohsiung (TW)

(21) Appl. No.: 18/942,364

(22) Filed: Nov. 8, 2024

(51) Int. Cl. H05K 1/02; H05K 1/18

(52) U.S. Cl. CPC H05K 1/028; H05K 1/0271; H05K 1/181; H05K 2201/057; H05K 2201/10522

(57) ABSTRACT

A package structure and a method of manufacturing a package structure are provided. The package structure includes a bent flexible carrier, a first component, and a flexible encapsulation layer. The first component is disposed on the bent flexible carrier. The flexible encapsulation layer encapsulates the first component and the bent flexible carrier.

### BACKGROUND

### 1. Field of the Disclosure

The present disclosure relates to a package module and a method of manufacturing a package module.

### 2. Description of the Related Art

Flexible electronics are widely used in wearable devices. However, the characteristics of the carrier of these electronics can be irreparably damaged after being stretched.

### SUMMARY

In some embodiments, a package module includes a bent flexible carrier, a first component, and a flexible encapsulation layer. The first component is disposed on the bent flexible carrier. The flexible encapsulation layer encapsulates the first component and the bent flexible carrier.

In some embodiments, a package module includes a flexible carrier, a first component, and a flexible encapsulation layer. The flexible carrier includes a first flat portion and a plurality of bending portions. The first component is disposed on the first flat portion. The flexible encapsulation layer encapsulates the flexible carrier and the first component. The first component is located between the bending portions.

In some embodiments, a package module includes a flexible carrier, a first component, a second component, and a flexible encapsulation layer. The flexible carrier includes a first flat portion and a second flat portion spaced apart from the first flat portion. The first component is disposed on the first flat portion. The second component is disposed on the second flat portion. The flexible encapsulation layer encapsulates the flexible carrier, the first component, and the second component. A relative position of the first component is configured to be adjustable with respect to the second component during a deformation of the package structure.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of a package structure according to some embodiments of the present disclosure.

FIG. 1A is a cross-sectional view of a package structure to which a deformation force is applied according to some embodiments of the present disclosure.

FIG. 1B is an enlarged cross-sectional view of a bending portion of a package structure to which a deformation force is applied according to some embodiments of the present disclosure.

FIG. 2 is a cross-sectional view of a package structure according to some embodiments of the present disclosure.

FIGS. 3A, 3B, and 3C illustrate one or more stages of an example of a method for manufacturing a package structure according to some embodiments of the present disclosure.

FIG. 4 is a cross-sectional view of a package structure according to some embodiments of the present disclosure.

FIG. 5 is a cross-sectional view of a package structure according to some embodiments of the present disclosure.

FIG. 6 is a cross-sectional view of a package structure according to some embodiments of the present disclosure.

FIG. 7 is a cross-sectional view of a package structure according to some embodiments of the present disclosure.

FIG. 8 is a cross-sectional view of a package structure to which a deformation force is applied according to some embodiments of the present disclosure.

FIG. 8A is an enlarged cross-sectional view of a bending portion of a package structure to which a deformation force is applied according to some embodiments of the present disclosure.

FIG. 9 is a cross-sectional view of a package structure according to some embodiments of the present disclosure.

FIG. 10 is a cross-sectional view of a package structure according to some embodiments of the present disclosure.

FIG. 11 is a top view of a package structure according to some embodiments of the present disclosure.

FIG. 12 is a cross-sectional view of a package structure to which a deformation force is applied according to some embodiments of the present disclosure.

FIG. 12A is an enlarged cross-sectional view of a bending portion of a package structure to which a deformation force is applied according to some embodiments of the present disclosure.

FIG. 13 is a cross-sectional view of a package structure according to some embodiments of the present disclosure.

FIG. 14 is a top view of a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The present disclosure relates to a package structure including a flexible carrier with a plurality of bending portions and a plurality of flat portions prior being encapsulated by a flexible encapsulant (e.g., silicon rubber). The bending portions may be formed by deliberately bending originally flat portions under thermal treatment. Since a redistribution layer (e.g., an electroplated metal layer) in the flexible carrier has high resilience to bending, the thermal bending process would not substantially affect the resistance of a redistribution layer (e.g., an electroplated metal layer) in the flexible carrier.

The flexible carrier may include an electroplated metal layer which has relatively poor resilience to a lateral tensile stress. During the application of the lateral tensile stress (e.g., stretching when being worn by a user) on the package structure (e.g., a wrist band), the deformation of the bending portions of the flexible carrier prevents the electroplated metal layer from being laterally stretched. In some embodiments, the curvature of the bending portions may be adjustable in response to the lateral tensile stress. This allows the package structure to be stretchable without damaging the electroplated metal layer or significantly increasing its resistance. When being stretched, the overall flexibility of the package structure can be increased via the deformation of the bending portions. At least one component (semiconductor die, system in package (SiP), sensor, or passive component) is disposed at a plurality of flat portions of the flexible carrier, to prevent damage to the connections (e.g., solder balls, solder paste) between the components and a conductive layer in the flexible carrier.

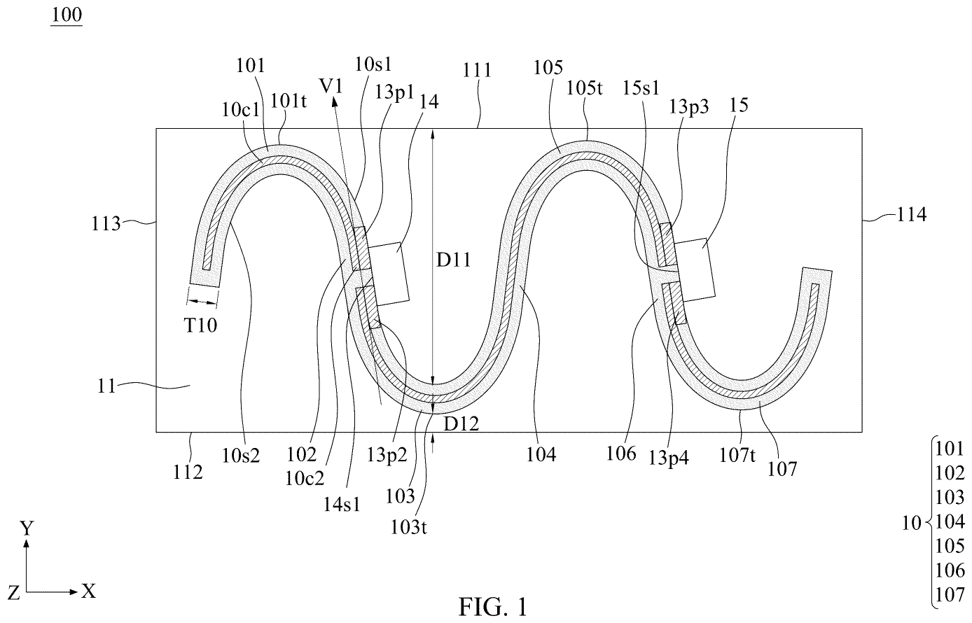

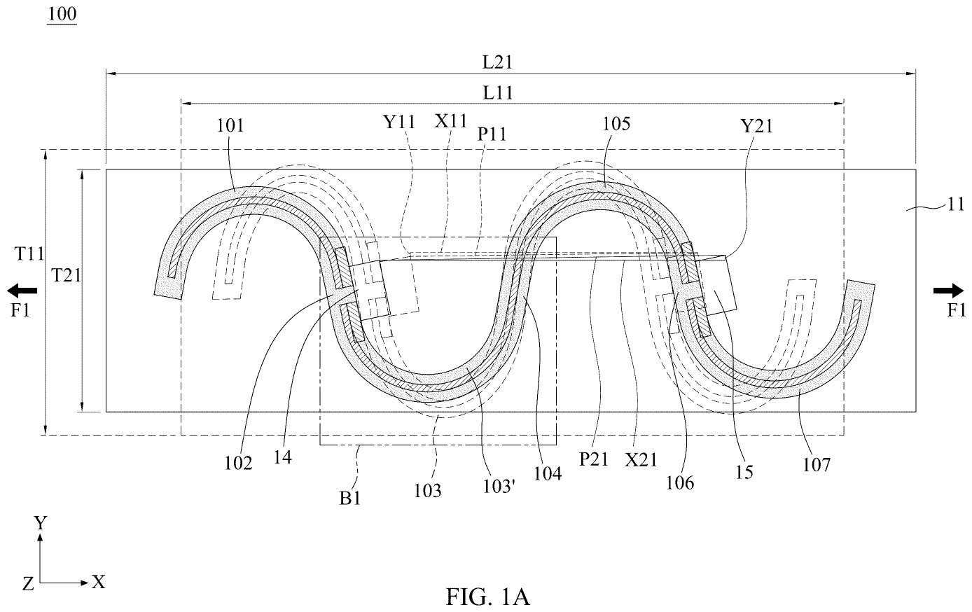

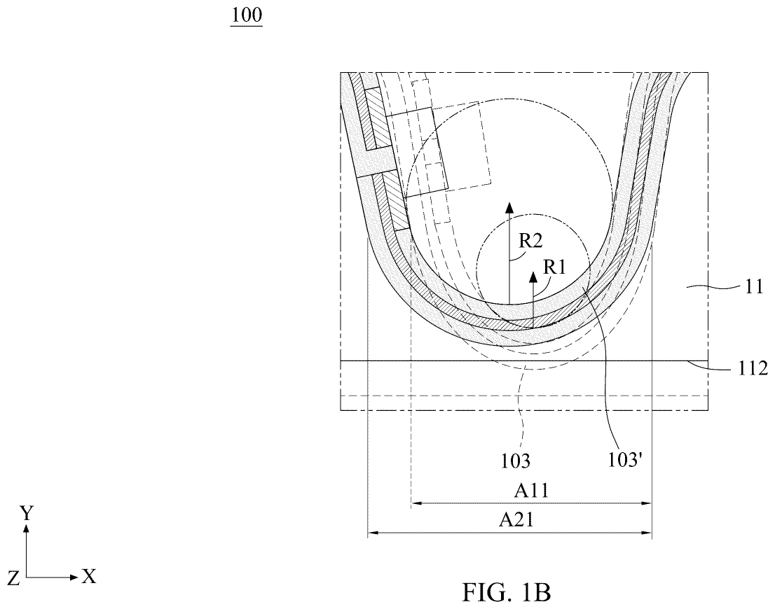

FIG. 1 is a cross-sectional view of a package structure according to some embodiments of the present disclosure. The package structure 100 may include a carrier 10, an encapsulation layer 11, a component 14, and a component 15.

The carrier (or a flexible carrier) 10 may be or include, for example, one or more of a printed circuit board, such as a paper-based copper foil laminate, a composite copper foil laminate, a polymer-impregnated glass-fiber-based copper foil laminate, and so on. In some arrangements, the carrier 10 includes pliable materials. An outline or shape of the carrier 10 may be configured to be adjustable or pliable. For example, the outline of the carrier 10 is pliable, flexible, bendable, and/or twistable. For example, the carrier 10 can be adjusted or bent to have a shape that conforms to any structure (e.g., a straight/flat or a non-straight/non-flat structure) of the electrical device. In some arrangements, the carrier 10 may include a flexible printed circuit (FPC). The carrier 10 can have a Young's modulus greater than about 1 gegapascal (GPa) or the elastic deformation is less than about 15%.

The substrate 10 may include an interconnection structure, such as a redistribution layer (RDL) and/or a grounding element. The RDL of the carrier 10 may include a conductive layer 10c1 and a conductive layer 10c2. The carrier 10 may include a dielectric layer (or an insulating layer) enclosing or surrounding the conductive layers 10c1 and 10c2. The conductive layer 10c1 may have a curved profile in a cross-sectional view. The conductive layer 10c2 may have a substantially flat profile in a cross-sectional view. The conductive layer 10c1 may be connected to the conductive layer 10c2.

In some embodiments, the conductive layers 10c1 and 10c2 may be formed of metal or metal alloy. The conductive layers 10c1 and 10c2 may include metal, such as copper, gold, silver, aluminum, titanium, tantalum, or the like. The conductive layers 10c1 and 10c2 may include electroplated metal layers. The conductive layer 10c1 may be formed by deliberately bending an originally flat conductive layer under thermal treatment. Since the conductive layer 10c1 (e.g., electroplated metal layers) has high resilience to bending, the thermal bending process would not substantially affect the resistance of the conductive layer 10c1. The resistances of the conductive layer 10c1 and the second conductive layer 10c2 may be substantially the same.

As shown in FIG. 1, a cross-section of the carrier 10 has a wave or “S” shape. The carrier 10 may have a substantially uniform thickness T10. The carrier 10 may include a plurality of bending portions (or bendable portions) 101, 103, 105, and 107. The carrier 10 may include a plurality of flat portions 102, 104, and 106. Each of the bending portions 101, 103, 105, and 107 and the flat portions 102, 104, and 106 may have the thickness T10. The flat portion 102 may be connected between the bending portions 101 and 103. The flat portion 104 may be connected between the bending portions 103 and 105. The flat portion 106 may be connected between the bending portions 105 and 107. The bending portions 101, 103, 105, and 107 may include the conductive layer 10c1, and the flat portions 102, 104, and 106 may include the conductive layer 10c2. The bending portion 103 may be connected between the flat portions 102 and 104. The bending portion 105 may be connected between the flat portions 104 and 106.

In some embodiments, the flat portions 102, 104, and 106 may be spaced apart from each other. The bending portions 101, 103, 105, and 107 may be spaced apart from each other.

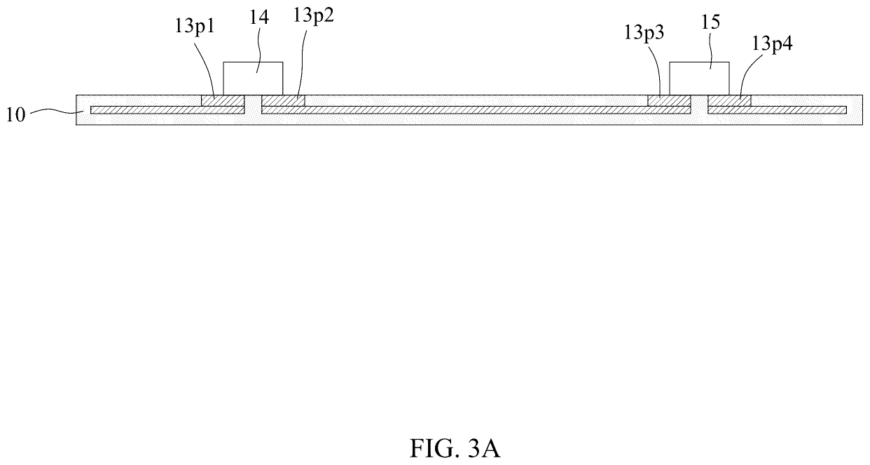

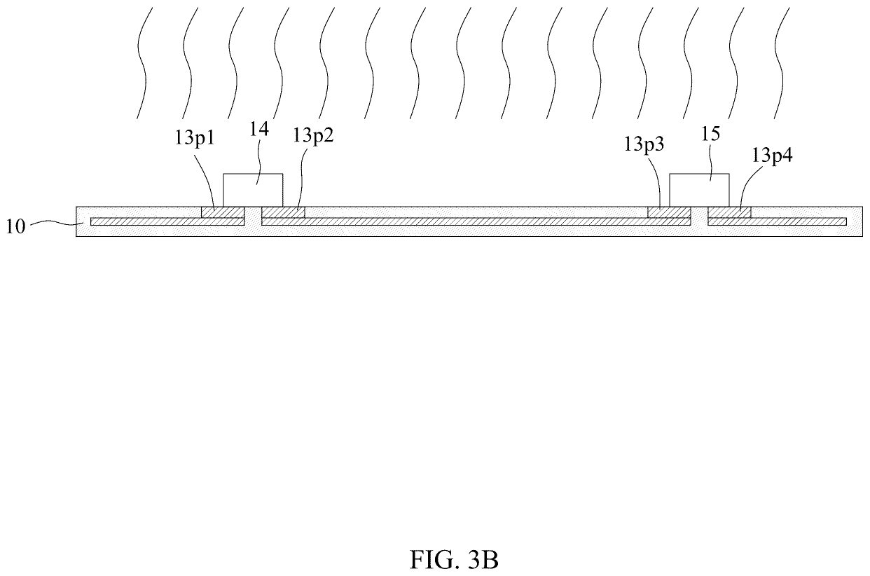

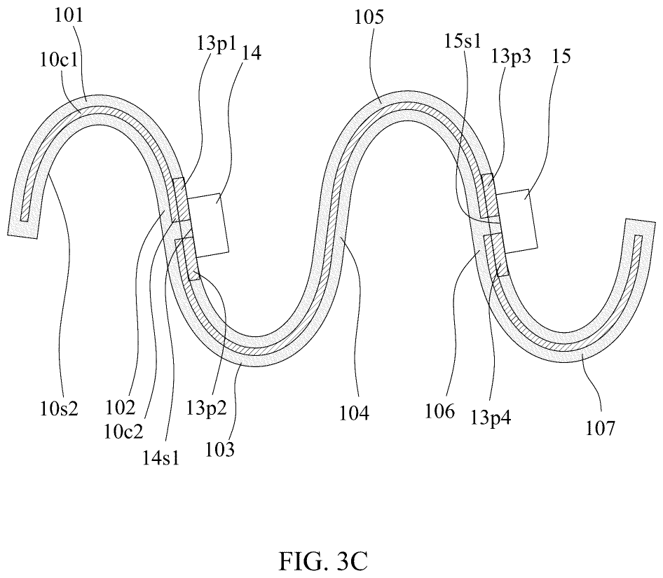

The bending portions 101, 103, 105, and 107 may have a curved profile in a cross-sectional view. The bending portions 101, 103, 105, and 107 may be formed by bending a flat portion of the package structure (see FIG. 3C). The carrier 10 may be bent prior to being encapsulated by the encapsulation layer 11. The carrier 10 may be a bent flexible carrier (or pre-bent flexible carrier, since it is bent prior to being encapsulated). The flat portions 102, 104, and 106 may have a substantially flat profile. The bending portions 101, 103, 105, and 107 may be more curved (or bending) than the flat portions 102, 104, and 106. Each of the bending portions 101, 103, 105, and 107 may have a curvature greater (or higher) than that of the flat portions 102, 104, and 106. In the present disclosure, “curvature” of a bending portion is defined through an osculating circle (as shown in FIG. 1B), which is the circle that best approximates the curve at a point. The “curvature” is the reciprocal of the radius of said osculating circle.

The package structure 100 may further include a plurality of conductive pads 13p1, 13p2, 13p3, and 13p4. The conductive pads 13p1 and 13p2 may be embedded in the flat portion 102 of the carrier 10. The conductive pads 13p1 and 13p2 may be connected to the conductive layer 10c2 in the flat portion 102. The conductive pads 13p3 and 13p4 may be embedded in the flat portion 106. The conductive pads 13p3 and 13p4 may be connected to the conductive layer 10c2 in the flat portion 106.

The carrier 10 may have a first surface 10s1 and a second surface 10s2 opposite to the first surface 10s1. The conductive pads 13p1, 13p2, 13p3, and 13p4 may be disposed at the first surface 10s1. The bending portions 101, 103, 105, and 107 and the flat portions 102, 104, and 106 may include (a part of) the first surface 10s1 and (a part of) the second surface 10s2.

The component 14 may be disposed on the first surface 10s1 of the carrier 10. The component 14 may be disposed on the flat portion 102 of the carrier 10. The component 14 may be disposed between the bending portions 101 and 103. The component 14 may be connected to the conductive pads 13p1 and 13p2. The number of the conductive pads for the connection between the component 14 and the carrier 10 may be more than two. In some embodiments, the carrier 10 may include a plurality of pins connecting to the component 14. In some embodiments, the component 14 may be connected to the conductive pads 13p1 and 13p2 through a plurality connection elements, such as, solder balls, controlled collapse chip connection (C4) bumps, a ball grid array (BGA), or a land grid array (LGA).

The component 15 may be disposed on the first surface 10s1 of the carrier 10. The component 15 may be disposed on the flat portion 106 of the carrier 10. The component 15 may be disposed between the bending portions 105 and 107. The component 15 may be connected to the conductive pads 13p3 and 13p4. The number of the conductive pads for the connection between the component 15 and the carrier 10 may be more than two. In some embodiments, the carrier 10 may include a plurality of pins connecting to the component 15. In some embodiments, the component 15 may be connected to the conductive pads 13p3 and 13p4 through a plurality connection elements, such as, solder balls, controlled collapse chip connection (C4) bumps, a ball grid array (BGA), or a land grid array (LGA).

The components 14 and 15 may be relatively rigid, e.g., compared to the carrier 10. In some embodiments, the components 14 and 15 may include, for example, a central processing unit (CPU), a microprocessor unit (MPU), a graphics processing unit (GPU), a microcontroller unit (MCU), a Neural network Processing Unit (NPU), an application-specific integrated circuit (ASIC), a photonic die, a field-programmable gate array (FPGA), or another type of integrated circuit. In some embodiments, the components 14 and 15 may include one or more processing elements and one or more memory elements electrically connected to the processing elements. In some embodiments, the processing element may be a CPU chiplet, a MCU chiplet, a GPU chiplet, an ASIC chiplet, or the like. The processing element(s) and the memory element(s) may be divided from or originate in a monolithic processing unit (e.g., a CPU, a MPU, a GPU, a MCU, an ASIC, or the like). In some embodiments, the components 14 and 15 may be a memory unit (or a data storage unit). The components 14 and 15 may include a memory. The components 14 and 15 may include dynamic random access memory (DRAM), static random access memory (SRAM), magnetoresistive random access memory (MRAM), flash memory, high bandwidth memory (HBM), or another suitable memory.

In some embodiments, the components 14 and 15 may include a system in package (SiP), a photonic module, and/or a fan out chip on substrate package (FoCoS). In some embodiments, the components 14 and 15 may include a passive component, such as a resistor, or an active component, such as an amplifier.

The encapsulation layer (or a flexible encapsulation layer) 11 may encapsulate the carrier 10 and the components 14 and 15. The encapsulation layer 11 may be transparent or opaque. In the present disclosure, to facilitate the explanation of the relationship and structure of the encapsulated elements, the carrier 10 and the components 14 and 15 can be viewed in the cross-sectional and top views.

The encapsulation layer 11 may be pliable. For example, the outline of the encapsulation layer 11 may be bendable, twistable, and/or stretchable. The encapsulation layer 11 may include a pliable material, a flexible material, or a soft material. The encapsulation layer 11 may include, but is not limited to, thermosetting polymer or thermoplastic polymer. The carrier 10 may include, but is not limited to, silicone rubber. The encapsulation layer 11 can include thermoplastic polyurethane (TPU), silicone, or the like. The encapsulation layer 11 can include a molding compound. The encapsulation layer 11 can include resin. The encapsulation layer 11 can include homogeneous material. The encapsulation layer 11 can be devoid of fillers. The encapsulation layer 11 can be devoid of particles. The encapsulation layer 11 can have a Young's modulus ranged from about 1 megapascal (MPa) to about 100 MPa. The Young's modulus of the carrier 10 may be greater than the Young's modulus of the encapsulation layer 11. The carrier 10 is more rigid than the encapsulation layer 11.

The encapsulation layer 11 may have a rectangular shape. The encapsulation layer 11 may have four sides (or outer sides) 111, 112, 113, and 114. The outer side (or a first surface) 111 may be opposite to the outer side (or a first surface) 112. The outer side (or a first lateral surface) 113 may be opposite to the outer side (or a second lateral surface 114). The outer sides 111 and 112 may extend in a direction (e.g., the X direction) substantially perpendicular to the outer sides 113 and 114.

The bending portions 101, 103, 105, and 107 may include top parts 101t, 103t, 105t, and 107t, respectively. The top parts 101t and 105t may face toward the side 111. The top parts 103t and 107t may face toward the side 112. The top part 103t of the bending portion 103 may be spaced apart from the side 111 with a first distance D11. The top part 103t of the bending portion 103 may be spaced apart from the side 112 with a second distance D12 different from the first distance D11. The first distance D11 may be greater than the second distance D12. The top part 101t of the bending portion 101 may be spaced apart from the sides 111 and 112 by different distances. The top part 105t of the bending portion 105 may be spaced apart from the sides 111 and 112 by different distances. The top part 107t of the bending portion 107 may be spaced apart from the sides 111 and 112 by different distances. The top part 105t may be closer to the side 111 than the top part 101t. The top part 103t may be closer to the side 111 than the top part 107t.

The flat portion 102 may extend in a direction V1 non-parallel to the four outer sides 111, 112, 113, and 114. The direction V1 may be non-perpendicular to the four outer sides 111, 112, 113, and 114. The components 14 and 15 may each have a long side extending in the direction V1. The component 14 may have a first surface 14s1 facing the flat portion 102 and tilted to the four outer sides 111, 112, 113, and 114. The component 15 may have a first surface 15s1 facing the flat portion 106 and tilted to the four outer sides 111, 112, 113, and 114.

FIG. 1A is a cross-sectional view of a package structure (e.g., the package structure 100) to which a deformation force F1 is applied according to some embodiments of the present disclosure. The package structure 100 (a wearable device, such as a wrist band, earphone, a headset, necklace, or the like) may be worn by a user. In order to wear the package structure 100, the user may temporarily or constantly apply the deformation force F1 to stretch the package structure 100. As shown in FIG. 1A, the deformation force F1 may be applied to the package structure 100 to adjust the profile of the package structure 100. A direction of the deformation force F1 may be parallel to the side 111 of the encapsulation layer 11 (or a long side of the package structure 100). The deformation force F1 may result in a lateral tensile stress on the package structure 100.

The package structure 100 in an “initial state” (without the application of the deformation force F1) is depicted with dashed lines. The package structure 100 in a “stretching state” (subjected to the deformation force F1) is depicted with solid lines.

The deformation force F1 may be applied to the package structure 100 to increase the length of the encapsulation layer 11 and decrease the thickness thereof. The encapsulation layer 11 may have a length L11 and a thickness T11 in the initial state of the package structure 100. The encapsulation layer 11 may have a length L21 and a thickness T11 in the stretching state of the package structure 100. The length L21 may be greater than the length L11. The thickness T11 may be greater than the thickness T21.

A relative position of the component 14 is configured to be adjustable with respect to the component 15 during a deformation of the package structure 100. The deformation of the package structure 100 may include the deformation of the encapsulation layer 11. The deformation force F1 may be applied to the package structure 100 to adjust a profile of the bending portions 101, 103, 105, and 107. The bending portions 101, 103, 105, and 107 may be deformed in response to the deformation force F1. The curvature of the bending portions 101, 103, 105, and 107 may be changed, and the details will be discussed in FIG. 1B. The deformation of the bending portions 101, 103, 105, and 107 may induce the adjustment of the relative position of the component 14. A relative position P11 of the component 14 with respect to the component 15 in the initial state of the package structure 100 is different from a relative position P21 of the component 14 with respect to the component 15 in the stretching state of the package structure 100.

In some embodiments, the relative positions P11 and P21 of the component 14 component 14 with respect to the component 15 may be referred to as a vector. The relative position P11 may have a component (or a distance) X11 in the X direction and a component Y11 (or a distance) in the Y direction. The X direction may be perpendicular to the Y direction. The relative position P21 may have a component (or a distance) X21 in the X direction and a component (or a distance) Y21 in the Y direction. The component X21 may be larger than the component X11. That is, a distance between the components 14 and 15 in the X direction may increase. The component Y21 may be smaller than the component Y11. That is, a distance between the components 14 and 15 in the Y direction may decrease. The direction of the components X11 and X21 may be the same (e.g., −X). The direction of the components X11 and X21 may be the same (e.g., −Y). In some embodiments, the direction of the component Y11 may be opposite to that of the component Y21. The component 14 may be higher than the component 15 in the initial state of the package structure 100, while the component 14 may be lower than the component 15 in the stretching state of the package structure 100.

In some embodiments, the relative position P11 (and P21) may have a component in the Z direction. The deformation force F1 may change the magnitude and/or direction of the component in the Z direction.

FIG. 1B is an enlarged cross-sectional view of a bending portion (e.g., the bending portion 103) of a package structure (e.g., the package structure 100) to which a deformation force F1 is applied according to some embodiments of the present disclosure. FIG. 1B may be an enlarged cross-sectional view of a box B1 in FIG. 1A.

The bending portions 101, 103, 105, and 107 may be configured to change when the deformation force F1 is applied to the package structure 100. A curvature of the bending portion 103 may be configured to change when the deformation force is applied to the package structure 100. The adjustment of the profile of the bending portion 103 may include changing a curvature of the bending portion 103. The bending portion in the initial state of the package structure 100 is denoted as 103, while the bending portion in the stretching state of the package structure 100 is denoted as 103′.

In the present disclosure, the “curvature” of a bending portion is defined through an osculating circle, which is the circle that best approximates the curve at a point. The “curvature” is the reciprocal of the radius of said osculating circle.

The curvature of the bending portion 103 may be defined through an osculating circle with a radius R1. The curvature of the bending portion 103′ may be defined through an osculating circle with a radius R2. The curvature of the bending portions 103 and 103′ is the reciprocal of the radius R1 and the radius R2, respectively. The radius R2 is larger than the radius R1, and thus the curvature of the bending portion 103 (103′) decreases.

The bending portion 103 has a projecting area A11 on the side 112 of the encapsulating layer 11. The bending portion 103′ has a projecting area A21 on the side 112 of the encapsulating layer 11. The projecting are A21 is larger than the projecting area A11. The bending portion 103 is laterally expanded (to be the bending portion 103′) during the application of the deformation force F1 by changing its curvature. The deformation of the other bending portions 101, 105, and 107 may be also applicable to the descriptions of FIG. 1B.

The conductive layers 10c1 and 10c2 (e.g., electroplated metal layer) may have relatively poor resilience to a lateral tensile stress. During the application of the lateral tensile stress (e.g., stretching when being worn by a user) on the package structure 100, the bending portions 101, 103, 105, and 107 of the carrier 10 may be adjustable in response to the lateral tensile stress. The bending portions 101, 103, 105, and 107 may be laterally expanded by adjusting (or changing) the curvature. The flexibility of the package structure 100 can be improved through the deformation of the bending portions 101, 103, 105, and 107. This allows the package structure 100 to be stretchable without damaging the conductive layers 10c1 and 10c2 or significantly increasing their resistance.

Furthermore, there is no or less stress applied to the flat portions 102, 104, and 106, and the risk of the delamination between the carrier 10 and the components 14 (and 15) can be reduced. There is no damage to the connections (e.g., solder balls, solder paste) between the component 14 (or 15) and the carrier 10. The electrical connection between the carrier 10 and the components 14 and 15 can be retained.

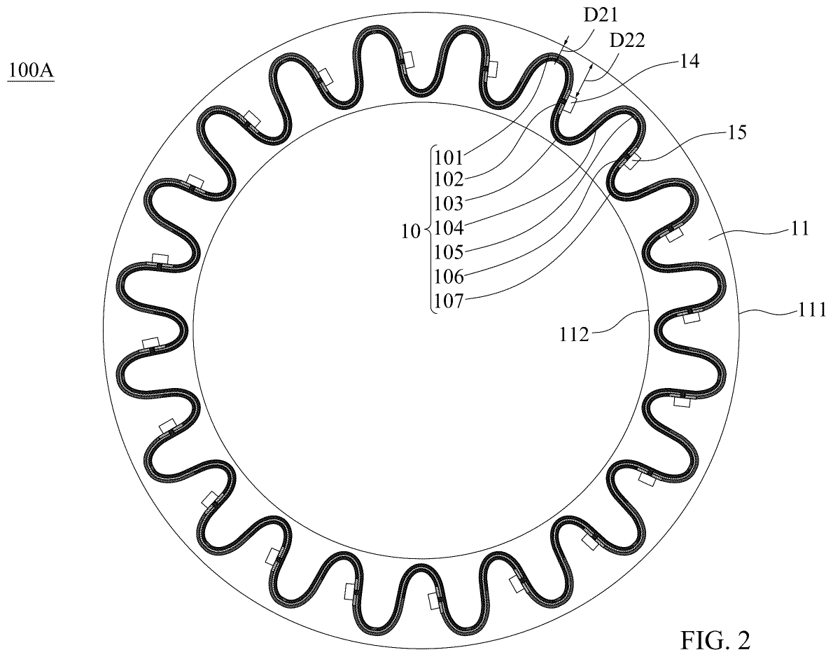

FIG. 2 is a cross-sectional view of a package structure 100A according to some embodiments of the present disclosure. A portion of the package structure 100A in FIG. 2 is similar to the package structure 100 in FIG. 1. In other words, the package structure 100A may be multiple package structure 100 seamlessly connected in series. Therefore, some detailed descriptions may refer to corresponding preceding paragraphs and are not repeated hereinafter for conciseness, with differences therebetween as follows.

The package structure 100A may have a ring structure. The encapsulation layer 11 may have a ring shape. The first surface 111 may be an outer surface of the ring structure and the second surface 112 opposite to the first surface may be an inner surface of the ring structure. The first surface 111 and the second surface 112 may be covered by the same material (i.e., the flexible encapsulation layer 11). The package structure 100A (a wearable device, such as a wrist band, earphone, a headset, necklace, or the like) may be worn by a user. In order to wear the package structure 100A, the user may temporarily or constantly apply a deformation force to stretch the package structure 100A. The deformation of the package structure 100A may be similar to those as described in the relevant texts of FIGS. 1A and 1B. In some embodiments, a portion of the package structure 100A may be deformed in a manner similar to the deformation shown in FIGS. 1A and 1B. Therefore, some detailed descriptions may refer to corresponding preceding paragraphs and are not repeated hereinafter for conciseness.

In some embodiments, a length of the inner surface of the ring structure (e.g., the second surface 112) is varied in response to the deformation of the encapsulation layer 11.

The bending portions 101 and 105 of the package structure 100A may be closer to the first surface 111 than to the second surface 112. The bending portions 103 and 107 of the package structure 100A may be further away from the first surface 111 than the second surface 112. The curvature of the bending portions 101 and 105 may be greater than that of the bending portions 103 and 107, since the bending portions 101 and 105 is stretched, while the bending portions 103 and 107 is compressed when manufacturing the ring structure of the package structure 100A.

In a radial direction, a distance D21 between the bending portion 101 (or 105) and the first surface 111 may be smaller than a distance D22 between the component 14 (or 15) and the first surface 111. The bending portion 101 (or 105) between the plurality of flat portions may be closer to the first surface 111 than the component 14 (or 15).

FIGS. 3A, 3B, and 3C illustrate one or more stages of an example of a method for manufacturing a package structure according to some embodiments of the present disclosure.

As shown in FIG. 3A, a carrier 10 is provided. The carrier 10 may have a substantially flat profile in a cross-sectional view. Components 14 and 15 may be mounted to the carrier 10. The component 14 may be connected to the carrier 10 through a plurality of conductive pads 13p1 and 13p2. The component 15 may be connected to the carrier 10 through a plurality of conductive pads 13p3 and 13p4.

As shown in FIG. 3B, a thermal treatment may be applied to the carrier 10. The carrier 10 may be more pliable than when disposed at a room temperature.

As shown in FIG. 3C, the carrier 10 may be secured to a bending tool (not shown) to deliberately bend a part of the carrier 10 to be a plurality of bending portions 101, 103, 105, and 107. The other part of the carrier 50, which supports the components 14 and 15, will be retained to be flat portions 102, 104, and 106. Afterwards, an encapsulation layer may be formed to encapsulate the carrier 10 and the components 14 and 15 to form the package structure 100 as shown in FIG. 1.

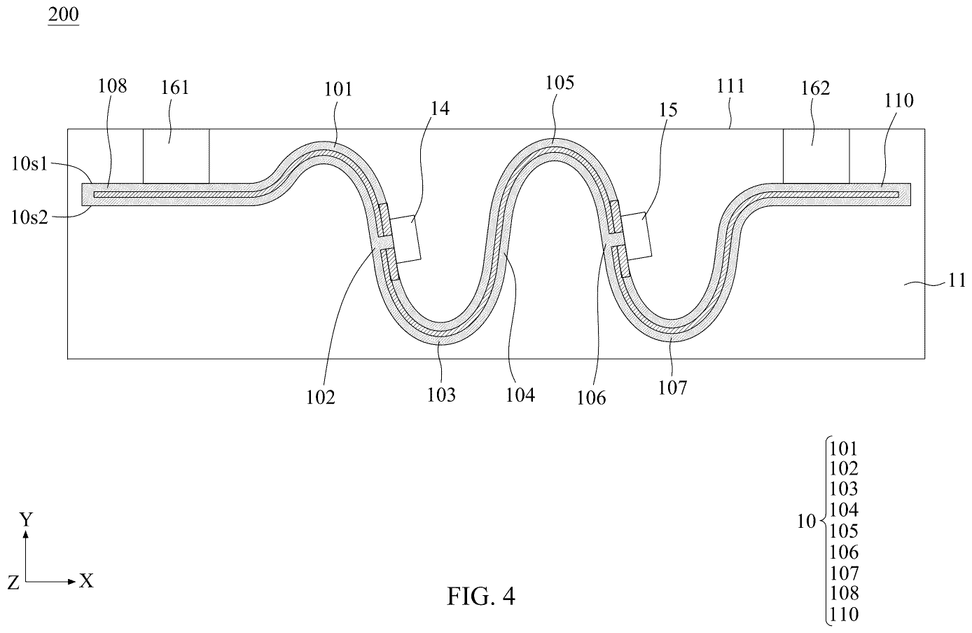

FIG. 4 is a cross-sectional view of a package structure 200 according to some embodiments of the present disclosure. The package structure 200 in FIG. 4 is similar to the package structure 100 in FIGS. 1, 2, and 2A. Therefore, some detailed descriptions may refer to corresponding preceding paragraphs and are not repeated hereinafter for conciseness, with differences therebetween as follows.

The package structure 200 may further include components (or input/output (I/O) units) 161 and 162 disposed on the first surface 10s1 of the carrier 10. The I/O units 161 and 162 may be encapsulated by the encapsulation layer 11. The I/O units 161 and 162 may be exposed by the side 111 of the encapsulation layer 11.

The I/O units 161 and 162 may be electrically connected to the components 14 and 15 through the carrier 10. The I/O units 161 and 162 may be electrically connected to an external device.

The carrier 10 may include a flat portion 108 connected to the bending portion 101 and a flat portion 110 connected to the bending portion 107. The I/O unit 161 may be disposed on the flat portion 108. The I/O unit 161 may be disposed on the flat portion 110.

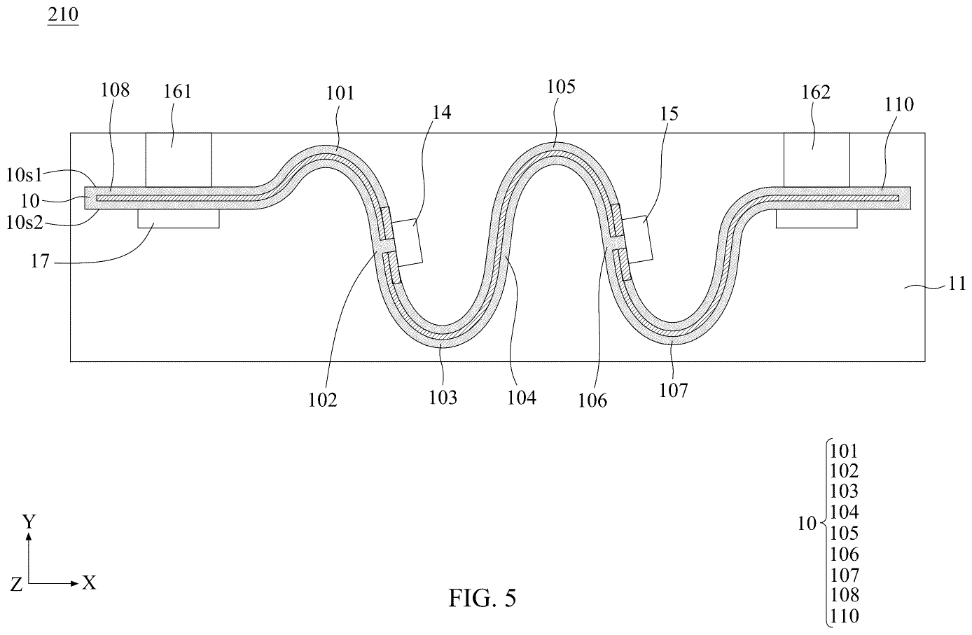

FIG. 5 is a cross-sectional view of a package structure 210 according to some embodiments of the present disclosure. The package structure 210 in FIG. 5 is similar to the package structure 200 in FIG. 4. Therefore, some detailed descriptions may refer to corresponding preceding paragraphs and are not repeated hereinafter for conciseness, with differences therebetween as follows.

The package structure 210 further includes a stiffener 17 disposed on the second surface 10s2 of the carrier 10. The stiffener 17 may be encapsulated by the encapsulation layer 11. The stiffener 17 may be disposed on the flat portions 108 and 110. The stiffener 17 may be configured to reduce the deformation of the flat portions 108 and 110. The stiffener 17 may be disposed below the I/O units 161 and 162. A projection of the stiffener 17 on the carrier 10 may overlap a projection of the I/O unit 161 (or 162) on the carrier 10. The stiffener 17 may be configured to prevent the delamination between the I/O units 161 and 162 and the carrier 10. In some embodiments, a stiffener may be disposed on the flat portions 102 or 106 configured to reduce the deformation thereof and prevent the delamination between the components 14 or 15 and the carrier 10.

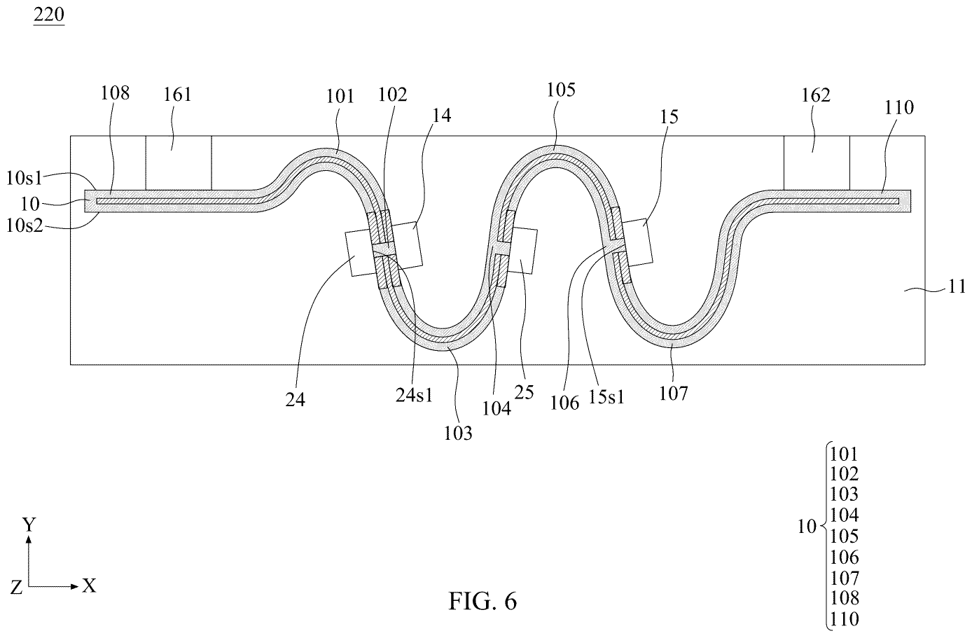

FIG. 6 is a cross-sectional view of a package structure 220 according to some embodiments of the present disclosure. The package structure 220 in FIG. 6 is similar to the package structure 200 in FIG. 4. Therefore, some detailed descriptions may refer to corresponding preceding paragraphs and are not repeated hereinafter for conciseness, with differences therebetween as follows.

The package structure 220 may further include a component 24 disposed on the flat portion 102. The component 24 may be disposed on the second surface 10s2 of the carrier 10. The component 24 may be disposed on a side (e.g., the second surface 10s2) of the flat portion 102 opposite to the other side (e.g., the first surface 10s1) on which the component 14 is disposed. The component 24 may be electrically connected to the carrier 10. The component 24 may be encapsulated by the encapsulation layer 11. The component 24 may have a surface 24s1 facing the flat portion 102. The surface 24s1 of the component 24 and the surface 15s1 of the component 15 face toward opposite directions. The component 24 may be located between the bending portions 101 and 103.

The package structure 220 may further include a component 25 disposed on the flat portion 104. The component 25 may be disposed on the first surface 10s1 of the carrier 10. The component 25 may be electrically connected to the carrier 10. The component 25 may be encapsulated by the encapsulation layer 11.

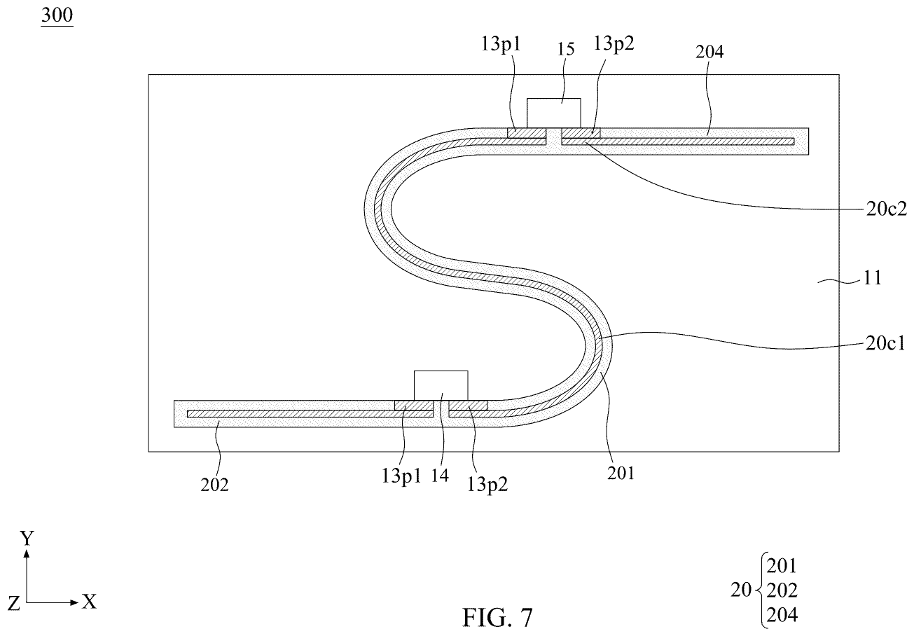

FIG. 7 is a cross-sectional view of a package structure 300 according to some embodiments of the present disclosure. The package structure 300 in FIG. 7 is similar to the package structure 100 in FIGS. 1, 2, and 2A. Therefore, some detailed descriptions may refer to corresponding preceding paragraphs and are not repeated hereinafter for conciseness, with differences therebetween as follows.

The package structure 300 may include a carrier 20, rather than the carrier 10. The carrier 20 may have materials similar to the carrier 10 of the package structure 100. The carrier 20 may be encapsulated by the encapsulation layer 11. The carrier 20 may include a bending portion (or a bendable portion) 201 and a plurality of flat portions 202 and 204. The bending portion 201 may be connected between the flat portions 202 and 204. The flat portions 202 and 204 may extend in a direction parallel to the sides 111 and 112 of the encapsulation layer 11. The component 14 may be disposed on the flat portion 202 and the component 15 may be disposed on the flat portion 204.

The bending portion 201 may have an “S” profile in a cross-sectional view. The bending portion 201 may have a curved profile in a cross-sectional view. The bending portion 201 may be formed by bending a flat portion of the package structure. The bending direction of the bending portion 201 may be different from those of the bending portions 101, 103, 105, and 107, and, thus, the package structure 300 may have a smaller thickness than the package structure 200. The flat portions 202 and 204 may have a substantially flat profile. The bending portion 201 may be more curved (or bending) than the flat portions 202 and 204. The bending portion 201 may have a curvature greater (or higher) than that of the flat portions 202 and 204.

The substrate 20 may include an interconnection structure, such as a redistribution layer (RDL) and/or a grounding element. The RDL of the carrier 20 may include a conductive layer 20c1 and a conductive layer 20c2. The carrier 20 may include a dielectric layer (or an insulating layer) enclosing or surrounding the conductive layers 20c1 and 20c2. The conductive layer 20c1 may have a curved profile in a cross-sectional view. The conductive layer 20c2 may have a substantially flat profile in a cross-sectional view. The conductive layer 20c1 may be connected to the conductive layer 20c2.

In some embodiments, the conductive layers 20c1 and 20c2 may be formed of metal or metal alloy. The conductive layers 20c1 and 20c2 may include metal, such as copper, gold, silver, aluminum, titanium, tantalum, or the like. The conductive layers 20c1 and 20c2 may include electroplated metal layers. The conductive layer 20c1 may be formed by deliberately bending an originally flat conductive layer under thermal treatment. Since the conductive layer 20c1 (e.g., electroplated metal layers) has high resilience to bending, the thermal bending process would not substantially affect the resistance of the conductive layer 20c1. The resistances of the conductive layer 20c1 and the second conductive layer 20c2 may be substantially the same.

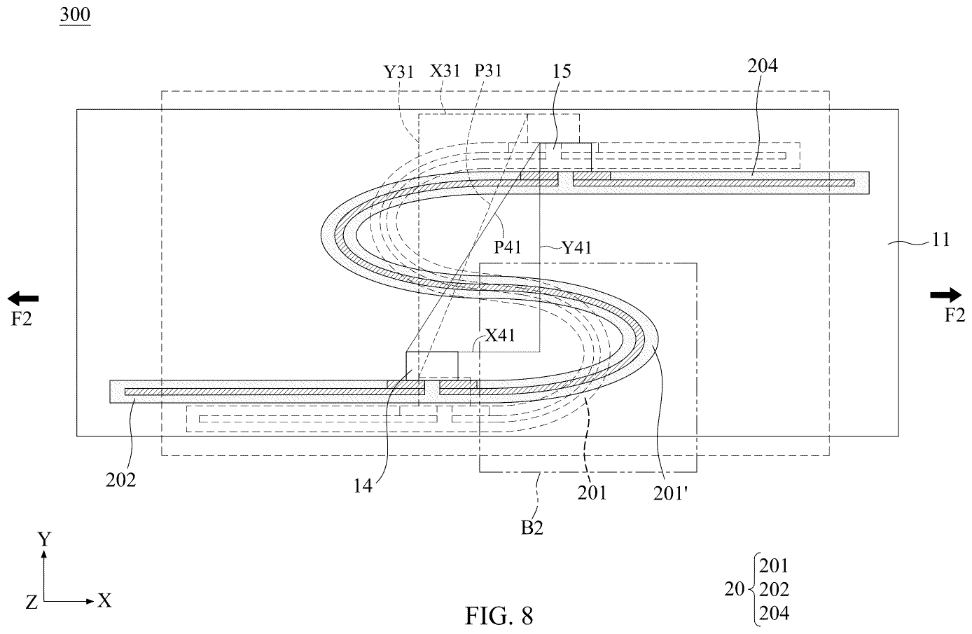

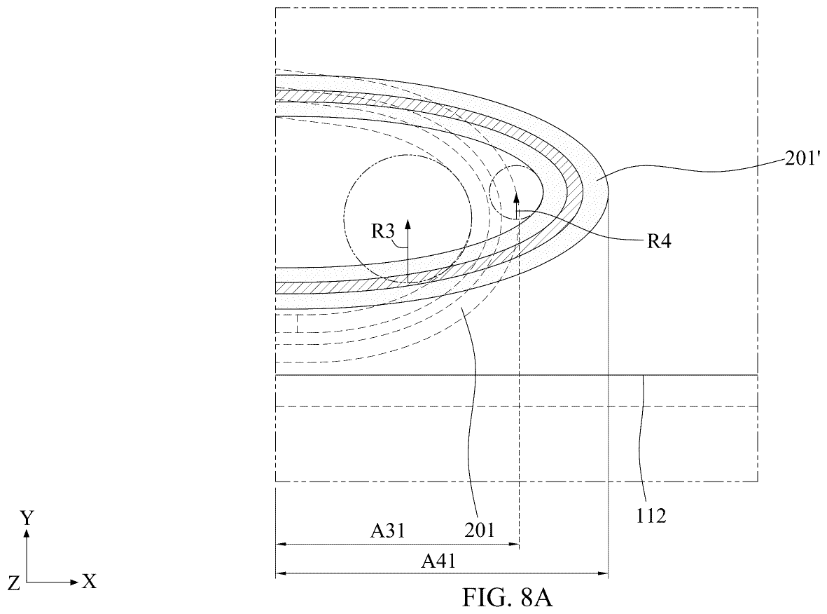

FIG. 8 is a cross-sectional view of a package structure 300 to which a deformation force F2 is applied according to some embodiments of the present disclosure. The package structure 200 (a wearable device, such as a wrist band, earphone, a headset, necklace, or the like) may be worn by a user. In order to wear the package structure 300, the user may temporarily or constantly apply the deformation force F2 to stretch the package structure 300.

As shown in FIG. 8, the deformation force F2 may be applied to the package structure 300 to adjust the profile of the package structure 300. A direction of the deformation force F2 may be parallel to the side 111 of the encapsulation layer 11 (or a long side of the package structure 300). The deformation force F2 may result in a lateral tensile stress on the package structure 300.

The package structure 300 in an “initial state” (without the application of the deformation force F2) is depicted with dashed lines. The package structure 300 in a “stretching state” (subjected to the deformation force F2) is depicted with solid lines.

The deformation force F2 may be applied to the package structure 300 to increase the length of the encapsulation layer 11 and decrease the thickness thereof.

A relative position of the component 14 is configured to be adjustable with respect to the component 15 during a deformation of the package structure 300. The deformation force F2 may be applied to the package structure 300 to adjust a profile of the bending portion 201. The bending portion 201 may be deformed in response to the deformation force F2. The curvature of the bending portion 201 may be changed, and the details will be discussed in FIG. 8A. The deformation of the bending portion 201 may induce the adjustment of the relative position of the component 14. A relative position P31 of the component 14 with respect to the component 15 in the initial state of the package structure 300 is different from a relative position P41 of the component 14 with respect to the component 15 in the stretching state of the package structure 300.

In some embodiments, the relative positions P31 and P41 of the component 14 with respect to the component 15 may be referred to as a vector. The relative position P31 may have a component (or a distance) X31 in the X direction and a component Y31 (or a distance) in the Y direction. The X direction may be perpendicular to the Y direction. The relative position P41 may have a component (or a distance) X41 in the X direction and a component (or a distance) Y41 in the Y direction. The component X41 may be larger than the component X31. That is, a distance between the components 14 and 15 in the X direction may increase. The component Y41 may be smaller than the component Y31. That is, a distance between the components 14 and 15 in the Y direction may decrease. The direction of the components X31 and X41 may be the same (e.g., −X). The direction of the components Y31 and Y41 may be the same (e.g., −Y).

In some embodiments, the relative position P31 (or P41) may have a component in the Z direction. The deformation force F1 may change the magnitude and/or direction of the component in the Z direction.

FIG. 8A is an enlarged cross-sectional view of a bending portion (e.g., the bending portion 201) of a package structure (e.g., the package structure 300) to which a deformation force F2 is applied according to some embodiments of the present disclosure. FIG. 8A may be an enlarged cross-sectional view of a box B2 in FIG. 8.

The bending portion 201 may be configured to change when the deformation force F2 is applied to the package structure 300. A curvature of the bending portion 201 may be configured to change when the deformation force is applied to the package structure 300. The adjustment of the profile of the bending portion 201 may include changing a curvature of the bending portion 201. The bending portion in the initial state of the package structure 300 is denoted as 201 while the bending portion in the stretching state of the package structure 300 is denoted as 201′.

The curvature of the bending portion 201 may be defined through an osculating circle with a radius R3. The curvature of the bending portion 201′ may be defined through an osculating circle with a radius R4. The curvature of the bending portions 201 and 201′ is the reciprocal of the radius R3 and the radius R4, respectively. The radius R4 is smaller than the radius R3, and thus the curvature of the bending portion 201 (201′) increases.

The bending portion 201 has a projecting area A31 on the side 112 of the encapsulating layer 11. The bending portion 201′ has a projecting area A41 on the side 112 of the encapsulating layer 11. The projecting area A41 is larger than the projecting area A31. The bending portion 201 is laterally expanded (to be the bending portion 201′) during the application of the deformation force F2 by changing its curvature.

The conductive layers 20c1 and 20c2 (e.g., electroplated metal layer) may have relatively poor resilience to a lateral tensile stress. During the application of the lateral tensile stress (e.g., stretching when being worn by a user) on the package structure 300, the bending portion 201 of the carrier 20 may be adjustable in response to the lateral tensile stress. The bending portion 201 may be laterally expanded by adjusting (or changing) the curvature. The flexibility of the package structure 300 can be improved through the deformation of the bending portion 201. This allows the package structure 300 to be stretchable without damaging the conductive layers 20c1 and 20c2 or significantly increasing their resistance.

Furthermore, there is little or no stress applied to the flat portions 202 and 204, and the risk of the delamination between the carrier 20 and the components 14 (and 15) can be reduced. There is no damage to the connections (e.g., solder balls, solder paste) between the component 14 (or 15) and the carrier 10. The electrical connection between the carrier 20 and the components 14 and 15 can be retained.

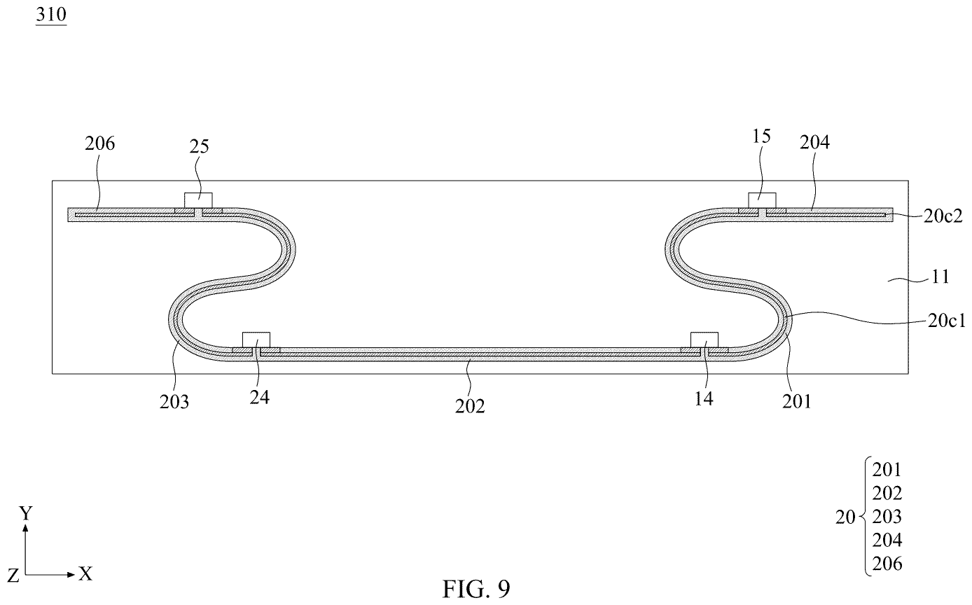

FIG. 9 is a cross-sectional view of a package structure according to some embodiments of the present disclosure. The package structure 310 in FIG. 9 is similar to the package structure 300 in FIGS. 7, 8, and 8A. Therefore, some detailed descriptions may refer to corresponding preceding paragraphs and are not repeated hereinafter for conciseness, with differences therebetween as follows.

The package structure 310 may further include a bending portion (or a bendable portion) 203 and a flat portion 206. The bending portion 204 is connected to the flat portion 202. The bending portion 204 may be connected between the flat portion 202 and the flat portion 206. The package structure 310 may further include a component 24 disposed on the flat portion 202 and a component 25 disposed on the flat portion 206.

The bending portion 203 may have an “S” profile in a cross-sectional view. The bending portion 203 may have a curved profile in a cross-sectional view. The bending portion 203 may be formed by bending a flat portion of the package structure. The flat portion 206 may have a substantially flat profile. The bending portion 203 may be more curved (or bending) than the flat portions 202 and 206. The bending portion 203 may have a curvature greater (or higher) than that of the flat portions 202 and 206. The carrier 20 may have a mirrored symmetrical profile in a cross-sectional view.

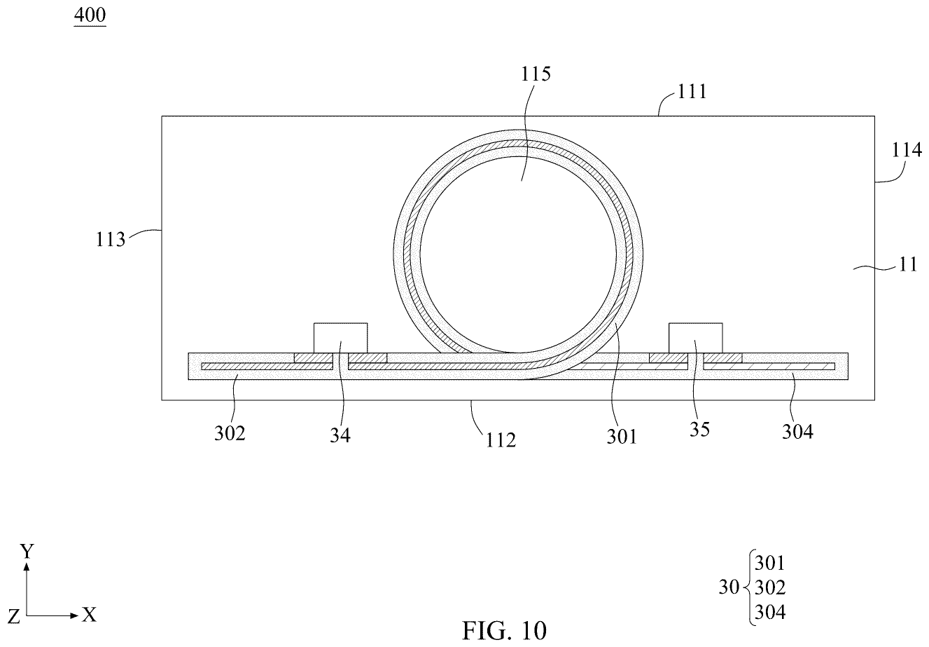

FIG. 10 is a cross-sectional view of a package structure 400 according to some embodiments of the present disclosure. The package structure 400 in FIG. 10 is similar to the package structure 100 in FIGS. 1, 2, and 2A. Therefore, some detailed descriptions may refer to corresponding preceding paragraphs and are not repeated hereinafter for conciseness, with differences therebetween as follows.

The package structure 400 may include a carrier 30, rather than the carrier 10. The carrier 30 may have material similar to the carrier 10 of the package structure 100. The carrier 30 may be encapsulated by the encapsulation layer 11. The carrier 30 may include a bending portion (or a bendable portion) 301 and a plurality of flat portions 302 and 304. The bending portion 301 may be connected between the flat portions 302 and 304. The flat portions 302 and 304 may extend in a direction parallel to the sides 111 and 112 of the encapsulation layer 11. The package structure 400 may include a component 34 disposed on the flat portion 302 and a component 35 disposed on the flat portion 304. The components 34 and 35 may be similar to the component 14, and detailed descriptions may refer to corresponding preceding paragraphs.

The bending portion 301 may have a circular profile in a cross-sectional view. The bending portion 301 may be formed by bending a flat portion of the package structure. The flat portions 302 and 304 may have a substantially flat profile. The bending portion 301 may be more curved (or bending) than the flat portions 302 and 304. The bending portion 301 may have a curvature greater (or higher) than that of the flat portions 302 and 304.

The substrate 30 may include an interconnection structure, such as a redistribution layer (RDL) and/or a grounding element. The RDL of the carrier 30 may include a conductive layer 30c1 and a conductive layer 30c2. The carrier 30 may include a dielectric layer (or an insulating layer) enclosing or surrounding the conductive layers 30c1 and 30c2. The conductive layer 30c1 may have a curved profile in a cross-sectional view. The conductive layer 30c2 may have a substantially flat profile in a cross-sectional view. The conductive layer 30c1 may be connected to the conductive layer 30c2.

In some embodiments, the conductive layers 30c1 and 30c2 may be formed of metal or metal alloy. The conductive layers 30c1 and 30c2 may include metal, such as copper, gold, silver, aluminum, titanium, tantalum, or the like. The conductive layers 30c1 and 30c2 may include electroplated metal layers. The conductive layer 30c1 may be formed by deliberately bending an originally flat conductive layer under thermal treatment. Since the conductive layer 30c1 (e.g., an electroplated metal layer) has high resilience to bending, the thermal bending process would not substantially affect the resistance of the conductive layer 30c1. The resistances of the conductive layer 30c1 and the second conductive layer 30c2 may be substantially the same.

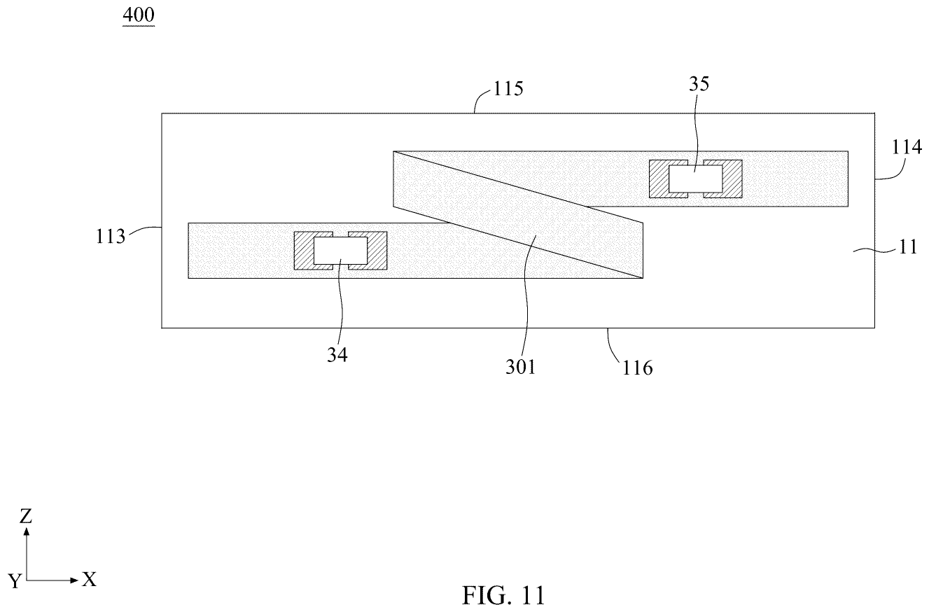

FIG. 11 is a top view of the package structure 400 according to some embodiments of the present disclosure. The carrier 30 may have a zigzag shape in a top view. The encapsulation layer 11 may have a side 115 and a side 116 opposite to the side 115. The sides 115 and 116 may be connected to the sides 113 and 114. The component 34 may be closer to the side 116 than to the side 115. The component 35 may be closer to the side 115 than to the side 116.

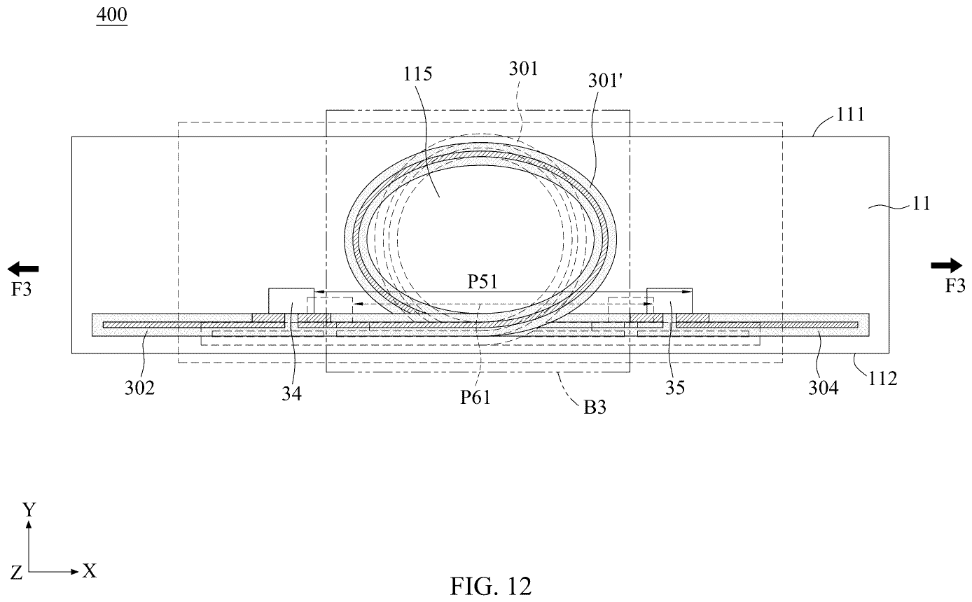

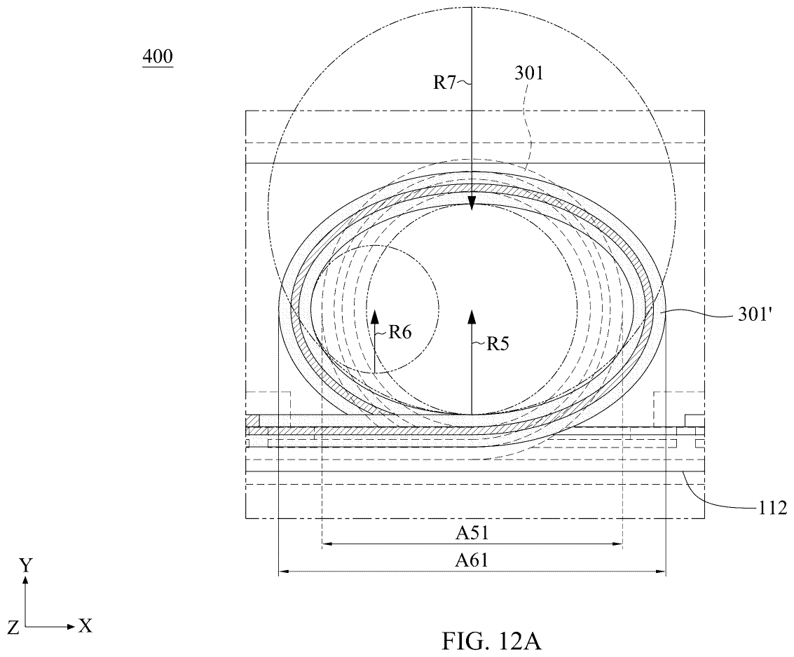

FIG. 12 is a cross-sectional view of a package structure (e.g., the package structure 400) to which a deformation force F3 is applied according to some embodiments of the present disclosure. The package structure 400 (a wearable device, such as, a wrist band, earphone, a headset, necklace, or the like) may be worn by a user. In order to wear the package structure 400, the user may temporarily or constantly apply the deformation force F3 to stretch the package structure 400.

As shown in FIG. 12, the deformation force F3 may be applied to the package structure 400 to adjust the profile of the package structure 400. A direction of the deformation force F3 may be parallel to the side 111 of the encapsulation layer 11 (or a long side of the package structure 400). The deformation force F3 may result in a lateral tensile stress on the package structure 400.

The package structure 400 in an initial state (without the application of the deformation force F3) is depicted with dashed lines. The package structure 400 in a stretching state (subjected to the deformation force F3) is depicted with solid lines.

The deformation force F3 may be applied to the package structure 400 to increase the length of the encapsulation layer 11 and decrease the thickness thereof.

A relative position of the component 34 is configured to be adjustable with respect to the component 35 during a deformation of the package structure 400. The deformation force F3 may be applied to the package structure 400 to adjust a profile of the bending portion 301. The bending portion 301 may be deformed in response to the deformation force F3. The curvature of the bending portion 301 may be changed, and the details will be discussed in FIG. 12A. The deformation of the bending portion 301 may induce the adjustment of the relative position of the component 34. A relative position P51 of the component 34 with respect to the component 35 in the initial state of the package structure 400 is different from a relative position P61 of the component 34 with respect to the component 35 in the stretching state of the package structure 400.

In some embodiments, the relative positions P51 and P61 of the component 34 with respect to the component 35 may be referred to as a vector. The relative position P51 may have a component (or a distance) X51 in the X direction or no component. The X direction may be perpendicular to the Y direction. The relative position P61 may have a component (or a distance) X61 in the X direction or no component. The component X61 may be larger than the component X51. That is, a distance between the components 34 and 35 in the X direction may increase. The direction of the components X51 and X61 may be the same (e.g., −X).

In some embodiments, the relative position P51 (or P61) may have a component in the Z direction. The deformation force F3 may change the magnitude and/or direction of the component in the Z direction.

FIG. 12A is an enlarged cross-sectional view of a bending portion (e.g., the bending portion 301) of a package structure (e.g., the package structure 400) subjected to the deformation force F3 according to some embodiments of the present disclosure.

The bending portion 301 may be configured to change when the deformation force F3 is applied to the package structure 400. One or more curvatures of the bending portion 301 may be configured to change when the deformation force is applied to the package structure 400. The adjustment of the profile of the bending portion 301 may include changing one or more curvatures of the bending portion 301. The bending portion in the initial state of the package structure 300 is denoted as 301 while the bending portion in the stretching state of the package structure 300 is denoted as 301′.

The curvature of the bending portion 301 may be defined through an osculating circle with a radius R5. A first curvature of a bottom (or top) section of the bending portion 301′ may be defined through an osculating circle with a radius R6. A second curvature of a lateral section of the bending portion 301′ may be defined through an osculating circle with a radius R7. The curvature of the bending portions 301 is the reciprocal of the radius R5. The bending portion 301′ may have a plurality of curvatures. The radius R6 is smaller than the radius R5, and thus the curvature of the lateral section of the bending portion 301 (301′) increases. The radius R7 is larger than the radius R5, and thus the curvature of the bottom (or top) section of the bending portion 301 (301′) decreases.

The bending portion 301 has a projecting area A51 on the side 112 of the encapsulating layer 11. The bending portion 301′ has a projecting area A61 on the side 112 of the encapsulating layer 11. The projecting are A61 is larger than the projecting area A51. The bending portion 301 is laterally expanded (to be the bending portion 301′) during the application of the deformation force F3 by changing its curvature.

The conductive layers 30c1 and 30c2 (e.g., electroplated metal layer) may have relatively poor resilience to a lateral tensile stress. During the application of the lateral tensile stress (e.g., stretching when being worn by a user) on the package structure 400, the bending portion 301 of the carrier 30 may be adjustable in response to the lateral tensile stress. The bending portion 301 may be laterally expanded by adjusting (or changing) the curvature. The flexibility of the package structure 400 can be improved through the deformation of the bending portion 301. This allows the package structure 400 to be stretchable without damaging the conductive layers 30c1 and 30c2 or significantly increasing their resistance.

Furthermore, there is little or no stress applied to the flat portions 302 and 304, and the risk of the delamination between the carrier 30 and the components 34 and 35 can be reduced. There is no damage to the connections (e.g., solder balls, solder paste) between the component 14 (or 15) and the carrier 10. The electrical connection between the carrier 30 and the components 34 and 35 can be retained.

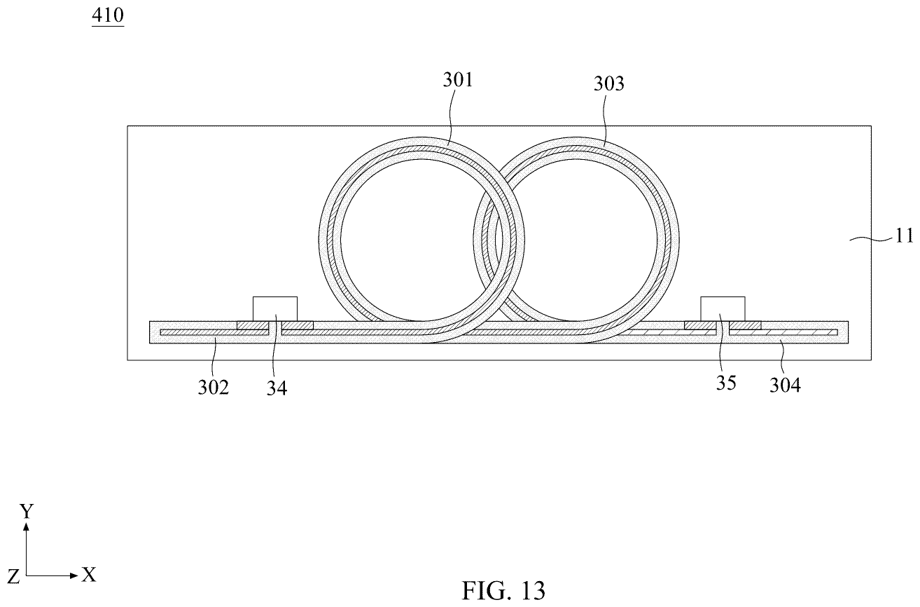

FIG. 13 is a cross-sectional view of a package structure 410 according to some embodiments of the present disclosure. The package structure 410 in FIG. 13 is similar to the package structure 400 in FIGS. 10, 12, and 12A. Therefore, some detailed descriptions may refer to corresponding preceding paragraphs and are not repeated hereinafter for conciseness, with differences therebetween as follows.

The carrier 30 of the package structure 410 may further include a bending portion (or a bendable portion) 303 connected to the bending portion 301. The profile or structure of the bending portion 303 may be similar to bending portion 303. The deformation of the bending portion 303 may be also applicable to the descriptions of FIG. 12A. In the cross-sectional view, the bending portion 301 and the second bending portion 303 of the carrier 30 may form a multiple-circular profile between the flat portions 302 and 304 of the carrier 30. The bending portions 301 and 303 may collectively form a spring shape in a cross-sectional view.

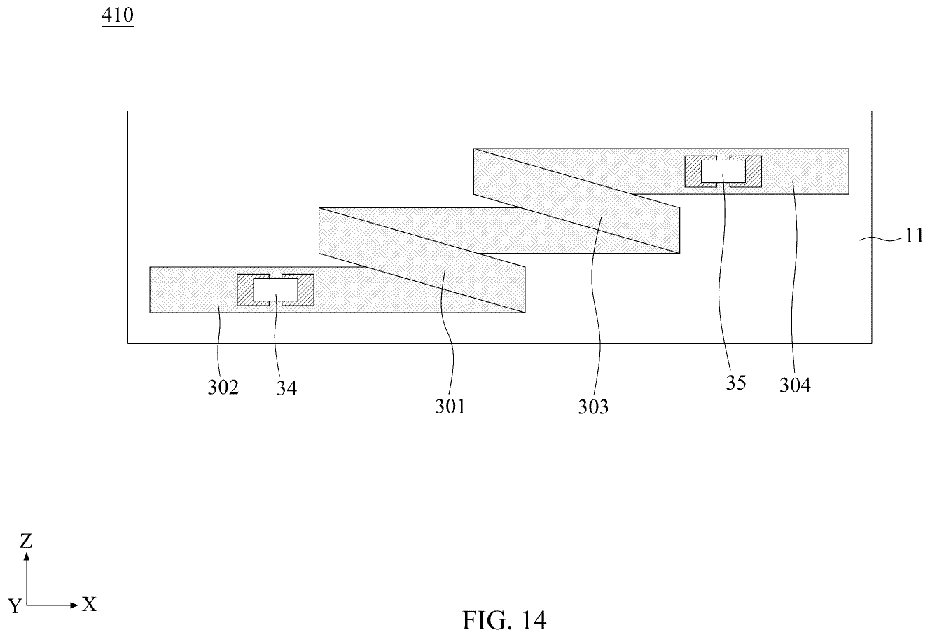

FIG. 14 is a top view of the package structure 410 according to some embodiments of the present disclosure. The carrier 30 may have a multiple zigzag shape in a top view.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a bent flexible carrier;
a first component disposed on the bent flexible carrier; and
a flexible encapsulation layer encapsulating the first component and the bent flexible carrier.

2. The package structure of claim 1, wherein the bent flexible carrier comprises a flat portion, wherein, in a cross-sectional view, the flexible encapsulation layer has four outer sides, and the flat portion extends in a direction non-parallel to the four outer sides.

3. The package structure of claim 2, wherein the direction is non-perpendicular to the four outer sides.

4. The package structure of claim 2, wherein the first component has a first surface facing the flat portion and tilted to the four outer sides.

5. The package structure of claim 1, wherein a bending portion of the bent flexible carrier is formed by bending a flat portion of the package structure.

6. The package structure of claim 1, wherein a first bending portion of the bent flexible carrier has a curved profile in a cross-sectional view.

7. The package structure of claim 6, wherein the first bending portion has a zigzag shape in a top view.

8. The package structure of claim 6, wherein, in a cross-sectional view, the first bending portion and a second bending portion of the bent flexible carrier form a multiple-circular profile between a plurality of flat portions of the bent flexible carrier.

9. The package structure of claim 1, wherein the bent flexible carrier has a substantially uniform thickness.

10. A package structure, comprising:
a flexible carrier comprising a first flat portion and a plurality of bending portions;
a first component disposed on the first flat portion; and
a flexible encapsulation layer encapsulating the flexible carrier and the first component,
wherein the first component is located between the bending portions.

11. The package structure of claim 10, wherein the bending portions are configured to change when a deformation force is applied to the package structure.

12. The package structure of claim 11, wherein a first curvature of at least one of the bending portions is configured to change when the deformation force is applied to the package structure.

13. The package structure of claim 12, wherein a second curvature of at least one of the bending portions is configured to change when the deformation force is applied to the package structure, and wherein the first curvature increases and the second curvature decreases.

14. The package structure of claim 10, further comprising a second component disposed on a first surface of the first flat portion opposite to a second surface on which the first component is disposed.

15. The package structure of claim 14, wherein the second component is located between the bending portions.

16. The package structure of claim 10, further comprising a stiffener disposed on a first surface of the first flat portion opposite to a second surface on which the first component is disposed.

17. A package structure, comprising:
a flexible carrier comprising a first flat portion and a second flat portion spaced apart from the first flat portion;
a first component disposed on the first flat portion;
a second component disposed on the second flat portion; and
a flexible encapsulation layer encapsulating the flexible carrier, the first component, and the second component,
wherein a relative position of the first component is configured to be adjustable with respect to the second component during a deformation of the package structure.

18. The package structure of claim 17, wherein the package structure has a ring structure.

19. The package structure of claim 18, wherein the ring structure has an inner surface, and a length of the inner surface is varied in response to a deformation of the flexible encapsulation layer.

20. The package structure of claim 18, wherein the ring structure has an outer surface, and the flexible carrier comprises a bending portion between the first flat portion and the second flat portion, and, in a radial direction, the bending portion is closer to the outer surface than the first component.
